(19) United States
(12) Patent Application Publication
(10) Pub. No.: US 2002/0185726 A1
(43) Pub. Date: Dec. 12, 2002

(54) Heat pipe thermal management of high potential electronic chip packages

(76) Inventors: Mark T. North, Lancaster, PA (US); Nelson J. Gernert, Elizabethtown, PA (US); Donald M. Ernst, Lancaster, PA (US)

Correspondence Address: DUANE MORRIS, LLP, ATTN: WILLIAM H. MURRAY, ONE LIBERTY PLACE, 1650 MARKET STREET, PHILADELPHIA, PA, 19103-7396, US

(21) Appl. No.: 09/875,231

(22) Filed: Jun. 6, 2001

(51) Int. Cl. H01L 23/10

(52) U.S. Cl. 257/707; 257/712; 257/719

(57) ABSTRACT

An improved electronic chip package is disclosed, which may include an electrical insulator, top and bottom metallization layers associated with said insulator, an integrated circuit (IC) device, and a heat pipe placed between the electrical insulator and the IC device, and soldered to the IC device, wherein the wall of the heat pipe may be constructed so that thermal stresses in the IC device are reduced.

### FIELD OF THE INVENTION

The present invention generally relates to improvements in packaging architecture for a high potential electronic chip package, in which the high heat flux produced by the chip is spread to a larger area before conducting through the insulating material, thereby reducing the thermal resistance of the related package.

### BACKGROUND OF THE INVENTION

A variety of approaches are known for dissipating heat generated by power semiconductor surface-mount (SM) devices. One approach is to use a ceramic substrate, such as alumina (Al₂O₃), beryllia (BeO), or another ceramic material that may be modified to promote its heat conduction capability. Heat-generating integrated circuit (IC) chips, such as insulated gate bipolar transistor (IGBT) chips, are often mounted to ceramic substrates that conduct and dissipate heat in a direction away from the chip. A heat sink may be attached to the opposite side of the substrate in order to dissipate heat to the surrounding environment. A heat sink may also be placed between the chip and substrate in order to increase heat transfer from the chip to the substrate. Because lateral heat transfer through a ceramic substrate is low compared to metals and metal-containing materials, power IC components have been mounted to thick-film conductors that increase heat transfer from the component downwardly to the underlying ceramic substrate.

One common packaging architecture for IGBTs involves soldering the chips (which operate at high potential), to a thin metallization layer on a ceramic insulator. Waste heat from the electronic device passes through the ceramic and is dissipated by a heat sink on the opposite side of the insulator. This architecture allows for relatively minimal heat spreading on the device side of the insulator, so that the high heat flux produced by the chip passes directly through the low thermal conductivity insulator. This results in a high temperature change between the high and low potential sides of the insulator. Another common packaging approach is to further mount the low potential side of the ceramic to another heat spreader, such as a copper plate. This, in turn, is mounted on a heat sink. The copper plate helps to further spread the heat before entering the heat sink.

### SUMMARY OF THE INVENTION

The present invention relates to an improvement to the above architecture, which comprises placing a heat pipe between the high voltage chip and the insulator to spread the high heat flux produced by the chip to a larger area, before it is conducted through the insulator. By reducing the heat flux that passes through the insulator, the thermal resistance of the package is significantly reduced. This enables higher heat flux operation of the chip; more particularly, in the case of IGBTs, this translates into higher switching rates being possible. In addition, further thermal resistance reduction occurs when a heat pipe is placed on the other side of the insulator.

### BRIEF DESCRIPTION OF THE DRAWINGS

The present invention will now be described with reference to the accompanying Figures, in which:

FIG. 1 is a side view of the prior art means for packaging IGBT devices; and

FIG. 2 is a side view of the improved IGBT package, with a heat pipe spreader on the high potential side of the insulator, in accordance with the present invention.

FIG. 3 is a side view of an alternative improved IGBT package, in accordance with the present invention.

FIG. 4 is a side view of an additional alternative improved IGBT package, in accordance with the present invention.

FIG. 5 is a side view of an additional alternative improved IGBT package, in accordance with the present invention.

FIG. 6 is a cross-section of FIG. 3.

FIG. 7 is a cross-section of FIG. 2.

### DETAILED DESCRIPTION OF THE INVENTION

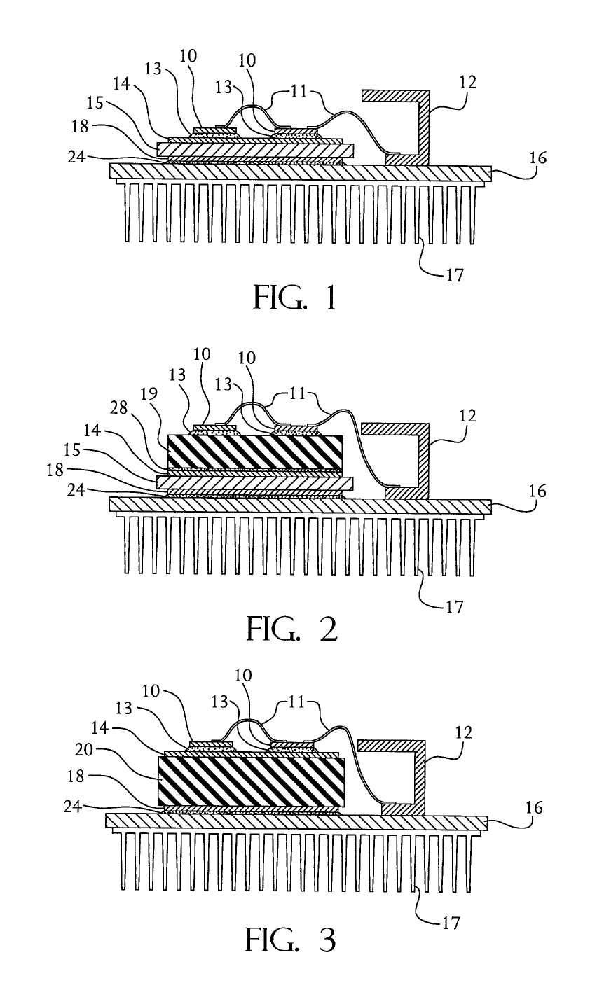

The present invention relates to an improvement in packaging architecture for power electronic devices, e.g., IGBTs, which improvement comprises placing a heat pipe between the chip and the insulator, in order to spread the high heat flux produced by the chip to a larger area, before it is conducted through the insulator. This is shown, e.g., in FIGS. 2-5. By reducing the heat flux that passes through the insulator, the thermal resistance of the overall package is reduced. Thus, this enables higher heat flux operation of the chip, and in the case of IGBTs, this translates into higher switching rates being possible.

Because the chips may be soldered directly to the heat pipe, it is likely that thermal stresses caused by the difference in the coefficient of thermal expansion (CTE) between the chip and the heat pipe could lead to failure of the chip. Note that in FIG. 1, the metallization layer is thin, so that the copper is forced into compression by the lower CTE of the silicon and ceramic materials. In FIG. 2, a preferred embodiment, this is mitigated by constructing the wall of the heat pipe thin enough so that thermal stresses in the wall, constructed of, e.g., copper, are not transmitted to the chip. The chips help reinforce the wall of the heat pipe in the “thin-wall” region.

The embodiments of the present invention will be further described below with reference being made to FIGS. 1-7.

FIG. 1 shows a side view of the prior art means for packaging IGBT devices, with FIGS. 2 and 3 illustrating preferred embodiments of the present invention. In FIGS. 1-3, a die (chip) 10 is attached by wire bonds 11 to a power terminal (power source) 12. A solder connection 13 connects the chips 10 to a top metallization layer 14, atop an electrical insulator 15. A bottom metallization layer 18 is in turn stacked atop a case wall (e.g., copper plate) 16, and is connected by solder connection 24. A heat sink 17 is at the bottom of the device. It is to be understood that e.g., a liquid cooling plate may be used in place of the heat sink 17 in order to achieve the purposes of the present invention. Please also note that multiple dies can be mounted to a single heat pipe.

In a preferred embodiment of the present invention, as shown in FIG. 2, a metal heat pipe 19 with at least two flat sides made of e.g., copper, is stacked between the solder connection 13 and top metallization layer 14. The metal heat pipe 19 is typically connected to top metallization layer 14 by solder connection 28. Thus, by placing the heat pipe 19 between the chip 10 and the insulator 15, higher heat flux operation of the chip 10 is possible. In the case of IGBTs, this translates into higher switching rates being possible. Further, general details regarding particular structures may be found in U.S. Pat. Nos. 5,408,128 and 5,826,645, herein incorporated by reference.

In an alternative preferred embodiment of the present invention, as shown in FIG. 3, an electrically insulating heat pipe 20 with at least two flat sides made of, e.g., ceramic, is stacked between the metallization layers 14 and 18. The ceramic substances may be, e.g., aluminum oxide, aluminum nitride, or beryllium oxide.

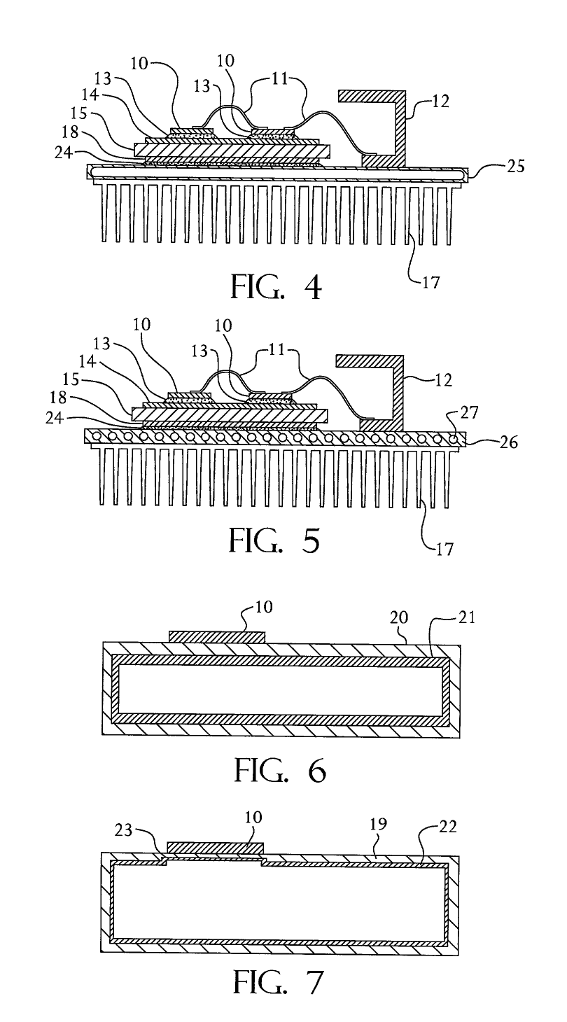

In a further alternative embodiment of the present invention, as shown in FIG. 4, the case wall 16 of FIG. 1 is replaced by a flat, hollow chamber heat pipe 25 or, alternatively, as shown in FIG. 5, a plate 26 with embedded heat pipes 27. These latter heat pipes 27 are embedded in a plate 26 constructed of, e.g., copper or aluminum; cylindrical heat pipes may be placed in holes within the plate. This construction provides low thermal resistance, is lightweight, and provides higher heat flux handling capacity. Uniform cooling of IGBT dies, as well as an isothermal surface at the base of the IGBT module are additional advantages.

FIG. 6, a cross section of FIG. 3, displays chip 10, heat pipe (e.g., ceramic) 20 and wick structure 21. Note that the wick structure 21 could be, e.g., sintered metal, grooves, sintered ceramic, or any other suitable capillary material. FIG. 7, a cross section of FIG. 2, in turn displays chip 10, heat pipe (e.g. copper) 19, wick 22 and thin-walled section 23 of heat pipe 19. The section 23 of heat pipe 19 under chip 10 is “thin-walled” so as to minimize the coefficient of thermal expansion (CTE) difference effects between chip 10 (low CTE) and the metal wall of heat pipe 19 (high CTE). The materials of heat pipe 20 and wick structure 21 may be a ceramic with a CTE that matches the chip 10.

While this invention has been described in terms of exemplary embodiments, it is not limited thereto. Rather, the appended claims should be construed broadly to include other variants and embodiments of the invention which may be made by those skilled in the art without departing from the scope and range of equivalents of the invention.

We claim:

1. An improved electronic chip package, comprising:
an electrical insulator;
top and bottom metallization layers associated with said insulator;
at least one integrated circuit (IC) device; and
at least one heat pipe placed between the electrical insulator and the IC device, and soldered to the IC device, wherein the wall of the heat pipe is constructed so that thermal stresses in the IC device are reduced.

2. The improved electronic chip package as recited in claim 1, further comprising a heat sink.

3. The improved electronic chip package as recited in claim 1, wherein the IC device is surface mounted.

4. The improved electronic chip package as recited in claim 1, wherein said heat pipe is constructed of copper.

5. The improved electronic chip package as recited in claim 1, wherein said IC device is an insulated gate bipolar transistor (IGBT) chip.

6. An improved electronic chip package, comprising:
a case wall;
top and bottom metallization layers;
at least one integrated circuit (IC) device; and
at least one electrically insulating heat pipe placed between the case wall and the IC device.

7. The improved electronic chip package as recited in claim 6, further comprising a heat sink.

8. The improved electronic chip package as recited in claim 6, wherein the IC device is surface mounted.

9. The improved electronic chip package as recited in claim 6, wherein said heat pipe is constructed of ceramic.

10. The improved electronic chip package as recited in claim 9, wherein said heat pipe is constructed of substances selected from the group consisting of aluminum oxide, aluminum nitride and beryllium oxide.

11. The improved electronic chip package as recited in claim 6, wherein said IC device is an insulated gate bipolar transistor (IGBT) chip.

12. An improved electronic chip package, comprising:
an electrical insulator;
top and bottom metallization layers associated with said insulator; and
at least one integrated circuit (IC) device, wherein the bottom metallization layer is connected to at least one heat pipe.

13. The improved electronic chip package as recited in claim 12, wherein the IC device is surface mounted.
